(19) United States
(12) Patent Application Publication
(10) Pub. No.: US 2024/0426670 A1
(43) Pub. Date: Dec. 26, 2024

(54) BOLOMETRIC DETECTOR

(71) Applicant: Commissariat à I'Énergie Atomique et aux Énergies Alternatives, Paris (FR)

(72) Inventors: Thomas Perrillat-Bottonet, Grenoble (FR); Jean-Jacques Yon, Grenoble (FR); Stéphane Pocas, Grenoble (FR)

(73) Assignee: Commissariat à I'Énergie Atomique et aux Énergies Alternatives, Paris (FR)

(21) Appl. No.: 18/748,422

(22) Filed: Jun. 20, 2024

(30) Foreign Application Priority Data
Jun. 22, 2023 (FR) 2306466

(51) Int. Cl. G01J 5/20; G01J 5/02; H10N 19/00

(52) U.S. Cl. CPC G01J 5/20; G01J 5/0205; H10N 19/00

(57) ABSTRACT

A bolometric detector comprising a plurality of pixels each including a bolometric plate suspended above a substrate by support pillars, the detector further including, for at least one of said pixels, a guided-mode filter including a planar waveguide resting on the support pillars, and a diffraction grating located on and in contact with the waveguide.

This application claims priority to French application number 2306466, filed Jun. 22, 2023. The contents of which is incorporated herein by reference in its entirety.

### TECHNICAL FIELD

The present description relates generally to the field of electronic devices, more particularly to bolometric detectors.

### BACKGROUND ART

Bolometric detectors or imagers operating in the infrared range have been proposed. For example, such detectors are capable of capturing infrared radiation in a wavelength range between a few micrometers and several hundred micrometers, for example between 3 and 20 μm, or more precisely between 7 and 14 μm (“LongWave InfraRed”, LWIR, band).

Among existing bolometric detectors, multispectral detectors in particular have been proposed. Unlike so-called “broadband” or “full-band” detectors, which are adapted to form a single image of a scene by exploiting their entire spectral sensitivity range, multispectral detectors are capable of producing several images of the same scene by exploiting different bands, or sub-ranges, within their spectral sensitivity range. This enables multispectral detectors, for example, to determine the temperature at several points in the scene to be imaged, with few assumptions about emissivity (absolute thermography). The information acquired by multispectral bolometric detectors can also be used to detect or distinguish chemical species present in the scene. An example of the application of this technique is gas detection, for example the detection of gas leaks on an industrial plant.

Multispectral bolometric detectors comprising a filter wheel placed opposite a bolometric sensor adapted to acquire an image for each filter on the wheel have been proposed. However, these detectors are bulky and require the scene to remain relatively still, or constant, for the image acquisition time. Furthermore, more compact multispectral bolometric detectors are also known, comprising a group of optical filters arranged opposite a bolometric sensor, some filters being adapted to transmit incident radiation mainly in a first wavelength range to some bolometers of the sensor, and other filters being adapted to transmit incident radiation mainly in at least one second wavelength range, different from the first wavelength range, to other bolometers of the sensor. In this case, each filter can comprise, for each pixel, elements located inside a quarter-wave cavity of the pixel, placed at an absorber of the pixel or offset above the pixel. The latter case avoids the need to introduce modifications impacting the bolometric pixel membrane or to add new elements to the quarter-wave cavity. This makes it easier to adapt known methods for producing bolometric pixels to the production of such detectors.

One proposed above-pixel filtering solution is based on the so-called “guided mode resonance” principle. A guided mode resonance filter, or GMR filter, typically comprises a planar waveguide coupled to a magnitude or phase diffraction grating. The planar waveguide is formed, for example, in a thin layer of high refractive index n (typically greater than 1.5) and transparent in the infrared range, the layer further having a thickness e matched to the median wavelength λ of the band of interest (e=λ/2n)). Furthermore, the diffraction grating is adapted to selectively couple infrared radiation whose wavelength has a first diffraction order corresponding to the acceptance angle of the waveguide, the period of the diffraction grating allowing the resonance wavelength to be selected. French patent FR 3054318 describes an example of GMR filter sizing, its coupling to an infrared bolometric pixel, and embodiments of the assembly.

The correct operation of a GMR filter is highly dependent on the periodicity of the structure formed by the diffraction grating. In the case of a bolometric matrix having a small pixel pitch and whose diffraction grating patterns is individualized for each pixel, this periodicity can be difficult to achieve. By way of example, to produce a resonance centered around 10 μm, the period of the diffraction grating is of the order of 3.5 μm. In the case of a pixel pitch of around 12 μm, the number of patterns per row or column of the diffraction grating is then, for each pixel, strictly less than 4. In this case, the spectral response of the GMR filter deviates significantly from an ideal case where the lateral extension of the diffraction grating is assumed to be infinite, and has multiple spurious resonances. This leads to a deterioration in the performance of the multispectral bolometric detector, resulting particularly in reduced pixel rejection performance and the appearance of crosstalk phenomena, or “optical crosstalk”, which tend to limit the efficiency of temperature reconstruction algorithms, distort the interpretation of the nature of chemical compounds present in the scene, etc.

### SUMMARY OF INVENTION

There is a need to overcome some or all of the drawbacks of existing bolometric detectors.

For this purpose, one embodiment provides a bolometric detector comprising a plurality of pixels each including a bolometric plate suspended above a substrate by support pillars, the detector further comprising, for at least one of said pixels, a guided-mode filter comprising a planar waveguide resting on the support pillars, and a diffraction grating located on and in contact with the waveguide.

According to one embodiment, the guided-mode filter comprises support elements resting on the support pillars.

According to one embodiment, each support element comprises an electrically conductive region whose sides and bottom are coated with an electrically insulating layer.

According to one embodiment, each support element is made of a single dielectric region.

According to one embodiment, at least two adjacent pixels of the detector comprise the guided-mode filter, the planar waveguides of said pixels being optically isolated by an electrically conductive region whose flanks and bottom are coated with an electrically insulating layer.

According to one embodiment, each support element comprises a dielectric region made of a first material, the sides and bottom of said region being coated with an insulating layer made of a second material, different from the first material.

According to one embodiment, the first material is amorphous silicon.

According to one embodiment, the second material is alumina.

According to one embodiment, at least two adjacent pixels comprise the guided-mode filter, the planar waveguides of said pixels being optically isolated by an electrically conductive region.

According to one embodiment, the electrically conductive region and the diffraction grating are made of a same material, preferably a metal.

According to one embodiment, the electrically conductive region and the diffraction grating are made of different materials, preferably metals.

According to one embodiment, the diffraction grating comprises a plurality of pads located on and in contact with the top face of the planar waveguide.

One embodiment provides a method for manufacturing a bolometric detector as described, the method comprising the following steps:
a) forming the support pillars and bolometric plates above the substrate;
b) depositing a first sacrificial layer on the side of the top face of the structure;
c) forming, for said at least one of said pixels, the planar waveguide and diffraction grating;
d) forming vias through the entire thickness of the first dielectric layer in line with each support pillar;
e) depositing a second insulating layer on the side of the top face of the structure; and
f) depositing an electrically conductive layer on the side of the top face of the structure.

According to one embodiment, step f) is implemented after step e).

According to one embodiment, step f) is implemented before step c).

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C, FIG. 1D, FIG. 1E, FIG. 1F, and FIG. 1G illustrate, with schematic and partial top, side and cross-sectional views, successive steps of an example method for manufacturing a bolometric detector according to one embodiment;

FIG. 2A, FIG. 2B, FIG. 2C, FIG. 2D, and FIG. 2E illustrate, with schematic and partial top, side and cross-sectional views, successive steps of an example method for manufacturing a bolometric detector according to one embodiment;

FIG. 3A, FIG. 3B, FIG. 3C, FIG. 3D, FIG. 3E, FIG. 3F, FIG. 3G, FIG. 3H, FIG. 3I, FIG. 3J, and FIG. 3K illustrate, with schematic and partial top, side and cross-sectional views, successive steps of an example method for manufacturing a bolometric detector according to one embodiment;

FIG. 4A and FIG. 4B illustrate, with schematic and partial side and cross-sectional views, a step in a variant of the method for manufacturing the bolometric detector shown in FIGS. 3A to 3K; and

FIG. 5A and FIG. 5B are graphs illustrating absorption spectra of bolometric pixels.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the steps for implementing the substrate, bolometer plates and support pillars have not been described in detail, as the embodiments described are compatible with the usual methods for implementing these elements.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

The term “transmittance of a layer” refers to a ratio between the intensity of radiation leaving a layer and the intensity of radiation entering the layer. In the rest of the description, a layer or film is said to be opaque to radiation when the transmittance of the radiation through the layer or film is less than 10%. In the rest of the description, a layer or film is said to be transparent to radiation when the transmittance of the radiation through the layer or film is greater than 10%.

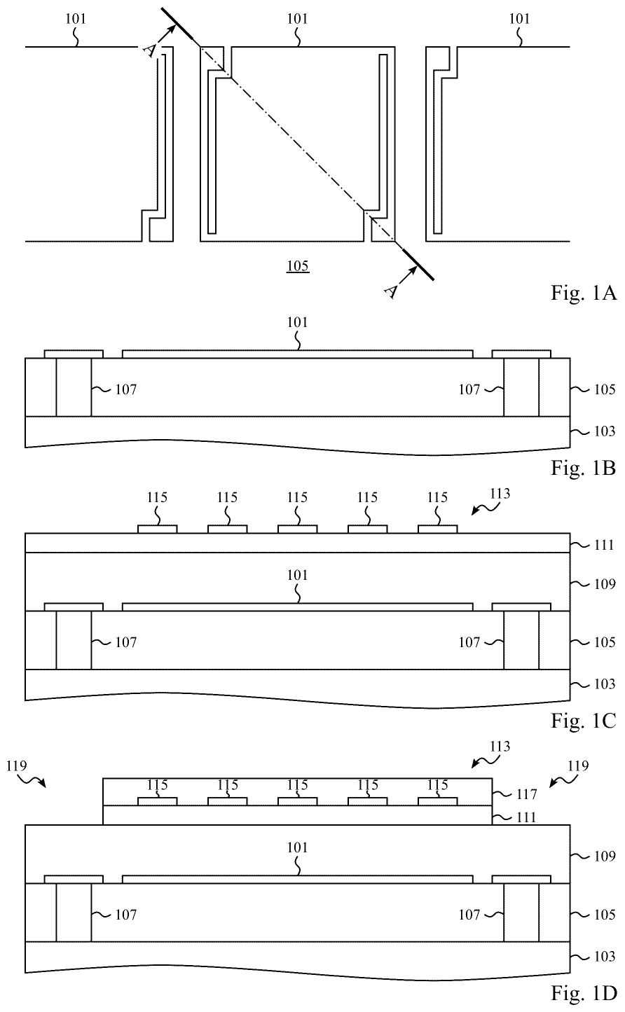

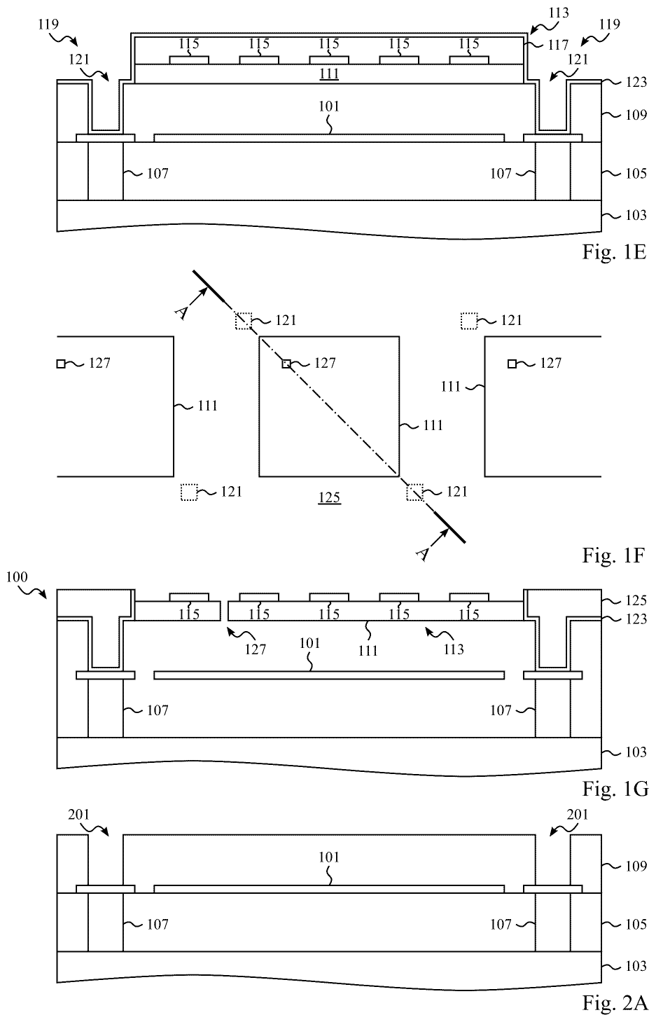

FIG. 1A, FIG. 1B, FIG. 1C, FIG. 1D, FIG. 1E, FIG. 1F, and FIG. 1G illustrate, with schematic and partial top, side and cross-sectional views, successive steps of an example method for manufacturing a bolometric detector 100 according to one embodiment.

FIG. 1A and FIG. 1B are respectively a schematic and partial top view and side and cross-sectional view along plane AA shown in FIG. 1A, of a step comprising forming a matrix of bolometric pixels.

In the example shown, each pixel includes a bolometer plate 101 located above a substrate 103, for example a wafer or a piece of wafer. For example, the substrate 103 is made of a semiconductor material, such as silicon. The substrate 103 is, for example, of the CMOS type (Complementary Metal-Oxide-Semiconductor). In this case, transistors, contact elements, conductive vias, etc. (not detailed in FIGS. 1A and 1B), suitable for driving the matrix pixels and acquiring signals from the pixels, are for example formed in the substrate 103. Although not detailed in FIGS. 1A and 1B, for example, the substrate 103 further comprises a reflector allowing a quarter-wave cavity to be formed with the bolometer plate 101.

In the illustrated example, a layer 105 coats one face of the substrate 103 (the upper face of substrate 103, in the orientation shown in FIG. 1B). The layer 105 is, for example, a sacrificial layer intended to be at least partially removed during the method of implementing the bolometric detector 100. By way of example, the layer 105 is a layer made of an electrically insulating material, for example silicon oxide, obtained for example via a precursor such as tetraethyl orthosilicate (TEOS). In the example shown, the bolometer plates 101 coat the face of layer 105 opposite the substrate 103 (the upper face of layer 105, in the orientation of FIG. 1B).

In the example shown, support pillars 107 for the bolometer plates 101 extend vertically through the thickness of the layer 105, from its upper face to the substrate 103. The support pillars 107 form vertical feet orthogonal to the upper face of the substrate 103 and are intended to suspend the bolometer plates 101 above the substrate 103 at the end of the steps for manufacturing the bolometer detector 100, for example after removal of the layer 105, with the support pillars 107 resting on the substrate 103. In the example shown, each bolometer plate 101 has, when viewed from above, a substantially square periphery and rests on two support pillars 107 arranged in the vicinity of two diagonally opposite corners of the bolometer plate 101. This example is not, however, limitative, as the bolometer plates 101 may, alternatively, have a periphery of any shape and rest on any number, for example higher than or equal to two, of support pillars 107 arranged in any way. In the example shown, support arms are used to mechanically secure each bolometer plate 101 to the corresponding support pillars 107. The support arms further enable the bolometer plate 101 to be coupled or to be electrically connected to the substrate 103, so that a signal can be read.

FIG. 1C is a partial schematic side view and cross-section along plane AA shown in FIG. 1A, illustrating a structure obtained at the end of a subsequent step of manufacturing the bolometric detector 100.

During this step, a sacrificial layer 109 is deposited on the side of the top face of the structure previously described in relation to FIG. 1B. The layer 109 coats the top face and side faces of the bolometer plates 101, and parts of the upper face of the layer 105 not coated by the bolometer plates 101. Layer 109 is, for example, a sacrificial layer intended to be at least partially removed during the method of manufacturing the bolometric detector 100. For example, the layer 109 has a thickness of between 500 nm and 2.5 μm, for example about 1.5 μm. By way of example, layer 109 is a layer made of an electrically insulating material, such as silicon oxide, obtained for example from a precursor such as tetraethyl orthosilicate. Layer 109 is made, for example, of the same material as layer 105.

Furthermore, a dielectric layer 111 is deposited on layer 109 during this step. In the orientation shown in FIG. 1C, the dielectric layer 111 coats the upper face of layer 109. Dielectric layer 111 is a dielectric layer intended to form a planar waveguide over bolometer plates 101. The dielectric layer 111 has, for example, a refractive index n and a thickness e equal to approximately λ/(2n), where λ represents the wavelength of interest of the bolometric detector 100. By way of example, the dielectric layer 111 is made of amorphous silicon and has a thickness e of between 500 nm and 2.5 μm, for example equal to approximately 1.6 μm for a wavelength range of interest λ of the bolometric detector 100 of between 8 and 14 μm.

Furthermore, an electrically conductive layer is deposited on the dielectric layer 111 during this step. A diffraction grating 113 is then formed from the electrically conductive layer, for example by photolithography followed by selective etching of the conductive layer with stop on the dielectric layer 111. In the example shown, the diffraction grating 113 includes a plurality of pads 115, the diffraction grating 113 then being, for example, a “magnitude” diffraction grating. The diffraction grating 113, for example, has a geometry, such as a pitch, individualized for each pixel, i.e. the pitch of the diffraction grating 113 can vary from one pixel to another. The electrically conductive layer in which the diffraction grating 113 is formed has a thickness, for example, of between 10 and 400 nm, for example around 50 nm. The pads 115, for example, have a thickness substantially equal to that of the conductive layer in which they are formed. By way of example, the electrically conductive layer is made of a metal, e.g. aluminum, tungsten, gold or silver, or of a metal alloy, e.g. an alloy based on aluminum and silicon (for example, with a silicon content of the order of 1%).

FIG. 1D is a partial schematic side view and cross-section along plane AA shown in FIG. 1A, illustrating a structure obtained at the end of a subsequent step of manufacturing the bolometric detector 100.

During this step, a layer 117 is deposited on the side of the top face of the structure previously described in relation to FIG. 1C. Layer 117 coats the top face and side faces of the pads 115 of diffraction grating 113, and parts of the upper face of dielectric layer 111 not coated by pads 115. For example, layer 117 has a thickness of between 100 and 500 nm, for example around 200 nm. By way of example, layer 117 is made of an electrically insulating material, such as silicon oxide, obtained for example from a precursor such as tetraethyl orthosilicate. For example, layer 117 is made of the same material as layer 109.

Furthermore, during this step, trenches 119 are formed in layers 117 and 111. The trenches 119 extend vertically through the thickness of layers 117 and 111 from the upper face of layer 117 to the upper face of layer 109. In the example shown, each trench 119 has, when viewed from above, an annular shape delimiting an island comprising a portion of the dielectric layer 111, a portion of the layer 117 and a portion of the diffraction grating 113 located opposite one of the bolometric plates 101. The trenches 119 associated with the various bolometer plates 101 may have common parts, with the trenches 119 forming a grid pattern, for example, when viewed from above. By way of example, the trenches 119 are formed by a photolithography step followed by a step for etching the layer 117 and then a step of etching the dielectric layer 111.

FIG. 1E is a schematic, partial side view and cross-section along plane AA shown in FIG. 1A, illustrating a structure obtained at the end of a subsequent step of manufacturing the bolometric detector 100.

During this step, vias 121 are formed through the layer 109, in line with the support pillars 107. In the example shown, the vias 121 extend through the entire thickness of the layer 109, i.e. extend vertically from the upper face of the layer 109 to the top face of the support pillars 107. In the example shown, the vias 121 have lateral dimensions substantially equal to those of the support pillars 107.

By way of example, the vias 121 are formed by a method comprising the following successive steps:
a) depositing a layer of carbonaceous material, e.g. Spin-on Carbon (SoC), on the side of the top face of the structure described above in relation to FIG. 1D;
b) creeping the carbonaceous material by heating, e.g. to a temperature of around 400° C.;
c) depositing a dielectric layer, for example an mineral layer made of silicon nitride or silicon oxide, coating the upper face of the layer of carbonaceous material;
d) depositing a layer made of a photoresist coating the upper face of the dielectric layer;
e) forming openings in the dielectric layer, by photolithography and then etching through the openings previously formed in the photoresist layer, followed by removing the photoresist layer, e.g. by stripping;
f) etching the layer made of carbonaceous material according to a self-aligned process through the openings formed in the dielectric layer during step e), the dielectric layer acting as a hard mask (thin mineral layer) during this step, followed by removal of the dielectric layer;
g) etching the layer 109 through the openings formed in the carbonaceous material layer in step f) with stop on the support pillars 107 of the bolometer plates 101, the carbonaceous material layer acting as a hard mask during this step; and
h) removing the layer made of carbonaceous material, for example by exposure to an oxygen-based plasma.

Furthermore, during this step, an insulating layer 123 is deposited on the side of the top face of the structure. The insulating layer 123 allows the bolometers to be isolated from the dielectric layer 111. In the orientation shown in FIG. 1E, insulating layer 123 coats the side faces and bottoms of vias 121, the parts of the upper face of layer 109 not coated by dielectric layer 111, the side faces of dielectric layer 111, and the upper face and side faces of layer 117. The insulating layer 123, for example, has a thickness of between 20 and 200 nm. By way of example, insulating layer 123 is made of a material resistant to a subsequent release operation by exposure to hydrofluoric acid in the vapor phase, for example aluminum nitride or alumina. For example, the insulating layer 123 is an alumina layer, for example, formed by Atomic Layer Deposition (ALD), and having a thickness of around 20 or 40 nm.

FIG. 1F and FIG. 1G are schematic and partial top view and side and cross-sectional view, respectively, along plane AA shown in FIG. 1F, illustrating a structure obtained at the end of a subsequent step of manufacturing the bolometric detector 100. The diffraction grating 113 and the layers 117 and 123 have not been shown in FIG. 1F so as not to overload the drawing.

During this step, a layer 125 is deposited on the side of the top face of the structure previously described in relation to FIG. 1E. In the example shown, layer 125 coats the insulating layer 123. Layer 125 fills the trenches 119 and vias 121, forming thus support elements or feet for a guided-mode resonance filter, or GMR filter, comprising waveguide 111 and diffraction grating 113. Layer 125 also acts as an optically insulating layer between the different pixels of bolometric detector 100. By way of example, layer 125 is made of a metal, such as tungsten, or a metal alloy.

Furthermore, during this step, layer 117 and layer 125 are thinned, for example by CMP (Chemical and Mechanical Polishing), the portion of layer 123 in contact with the upper face of layer 117 being removed by the CMP operation. Layer 117 then has a thickness slightly higher than that of the pads 115 of diffraction grating 113, and only parts of layer 125 filling the trenches 119 and vias 121 are kept.

Furthermore, during this step, release vents 127 are formed in the thickness of layers 117 and 111, for example by photolithography and subsequent etching. For example, release by exposure to hydrofluoric acid in the vapor phase is then implemented, for example, so as to remove layers 105, 109 and 117, thereby suspending the bolometric plates 101 of detector 100 above substrate 103. In this example, the GMR filter of the bolometric detector 100 then rests on the support pillars 107 of the bolometric plates 101, the bottom face of each GMR filter support element being on and in contact with the top face of the opposing support pillar 107.

In this example, the parts of layer 125 remaining at the end of the steps of manufacturing the bolometric detector 100 are interconnected. The parts of layer 125 act, for example, as an optical isolator allowing the crosstalk phenomena, or optical crosstalk, between the various pixels of the bolometric detector 100 to be limited. In the example shown, the support elements of the GMR filter comprise an electrically conductive region, in this case a part of layer 125, whose sides and bottom are coated with an electrically insulating layer, in this case a part of layer 123.

In the example shown, the optical isolator is ring-shaped when viewed from above. This allows optimum optical performance to be reached.

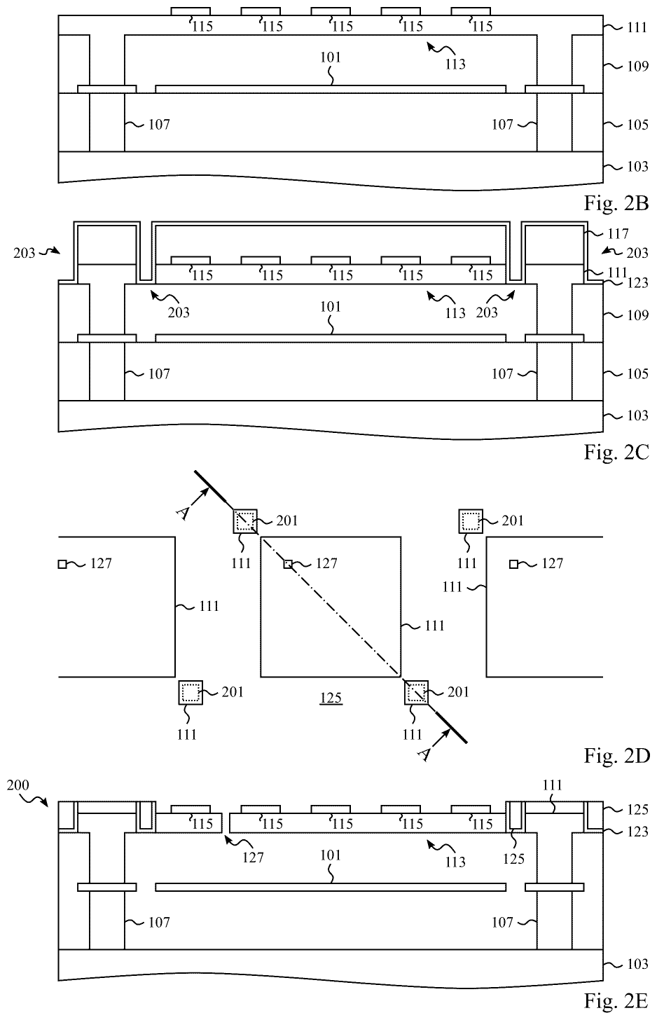

FIG. 2A, FIG. 2B, FIG. 2C, FIG. 2D, and FIG. 2E illustrate, with schematic and partial top, side and cross-sectional views, successive steps in an example method for manufacturing a bolometric detector 200 according to one embodiment.

The method for manufacturing the bolometric detector 200 is similar to the method for manufacturing the bolometric detector 100 described in detail above. The method for manufacturing the bolometric detector 200 differs from the method for manufacturing the bolometric detector 100 in that, during the method for manufacturing the bolometric detector 200, the layer 109 is etched, so as to subsequently form the support elements of the GMR filter, prior to depositing the dielectric layer 111.

FIG. 2A is a partial schematic side and cross-sectional view along plane AA shown in FIG. 1A, illustrating a structure obtained at the end of a step of manufacturing the bolometric detector 200 comprising depositing layer 109, on the side of the top face of the structure previously described in relation to FIGS. 1A and 1B.

Furthermore, during this step, vias 201 are formed in layer 109, in line with support pillars 107. In the example shown, vias 201 pass through the entire thickness of layer 109 and extend vertically from the upper face of layer 109 to the top face of support pillars 107. In the example shown, the vias 201 have lateral dimensions substantially equal to those of the support pillars 107. The vias 201 are formed, for example, by photolithography followed by etching, with stop on the top layer of the support pillars 107.

FIG. 2B is a partial schematic side and cross-sectional view along plane AA shown in FIG. 1A, illustrating a structure obtained at the end of a subsequent step of manufacturing the bolometric detector 200.

During this step, the dielectric layer 111 is deposited on the side of the top face of the structure previously described in relation to FIG. 2A. In the example shown, the dielectric layer 111 fills, i.e. completely fills, the vias 201 and coats the upper face of the layer 109. However, this example is not limitative, as the dielectric layer 111 may alternatively coat the sides and bottom of the vias 201 without filling them.

In addition, during this step, the pads 115 of the diffraction grating 113 are formed on the upper face of the dielectric layer 111, for example as previously described in relation to FIG. 1C.

FIG. 2C is a partial schematic side and cross-sectional view along plane AA shown in FIG. 1A, illustrating a structure obtained at the end of a subsequent step of manufacturing the bolometric detector 200.

During this step, layer 117 is deposited on the side of the top face of the structure previously described in relation to FIG. 2B.

Furthermore, during this step, trenches 203 are formed in layer 117 and in dielectric layer 111. In the example shown, trenches 203 extend vertically through the thickness of layers 117 and 111, from the upper face of layer 117 to the upper face of layer 109. For example, when viewed from above, trenches 203 have an annular shape delimiting parts of layers 111 and 117 located in line with the bolometer plate 101, and parts of layers 111 and 117 located in line with the support pillars 107. Thus, unlike the embodiment previously described in relation to FIGS. 1A to 1G, the geometry of trenches 203 spares the support zones, no trenches 203 being, in this case, located in line with the support elements of the GMR filter.

Furthermore, during this step, the insulating layer 123 is deposited on the side of the top face of the structure. In the example shown, layer 123 coats the sides and bottom of trenches 203, as well as the upper face of layer 117.

FIG. 2D and FIG. 2E are, respectively, a schematic and partial top view and side and cross-sectional view along plane AA shown in FIG. 2D, illustrating a structure obtained at the end of a subsequent step of manufacturing the bolometric detector 200. The diffraction grating 113 and the layers 117 and 123 have not been shown in FIG. 2D so as not to overload the drawing.

During this step, layer 125 is deposited on the side of the top face of the structure previously described in relation to FIG. 2C. In the example shown, layer 125 coats insulating layer 123. Layer 125 fills the trenches 203 and acts as an optically insulating layer between the different pixels of the bolometric detector 200.

Furthermore, during this step, layer 117 and layer 125 are thinned, for example by CMP, the portion of layer 123 in contact with the upper face of layer 117 being removed by the CMP operation. Layer 117 then has a residual thickness slightly greater than that of the pads 115 of diffraction grating 113, and only parts of layer 125 filling the trenches 203 are kept.

Furthermore, during this step, release vents 127 are formed through the thickness of layers 117 and 111, for example by photolithography and subsequent etching. Releasing by exposure to hydrofluoric acid in the vapor phase is then implemented, for example, to remove layers 105, 109, and 117, thereby suspending the bolometer plates 101 of detector 200 above substrate 103.

In this example, the parts of layer 125 remaining at the end of the steps for manufacturing the bolometric detector 200 are interconnected, and the support elements of the GMR filter are made entirely of a dielectric material, in this particular case the material of layer 111. Optical isolation between the pixels of the detector 200 is provided by parts of the layer 125 of the GMR filter.

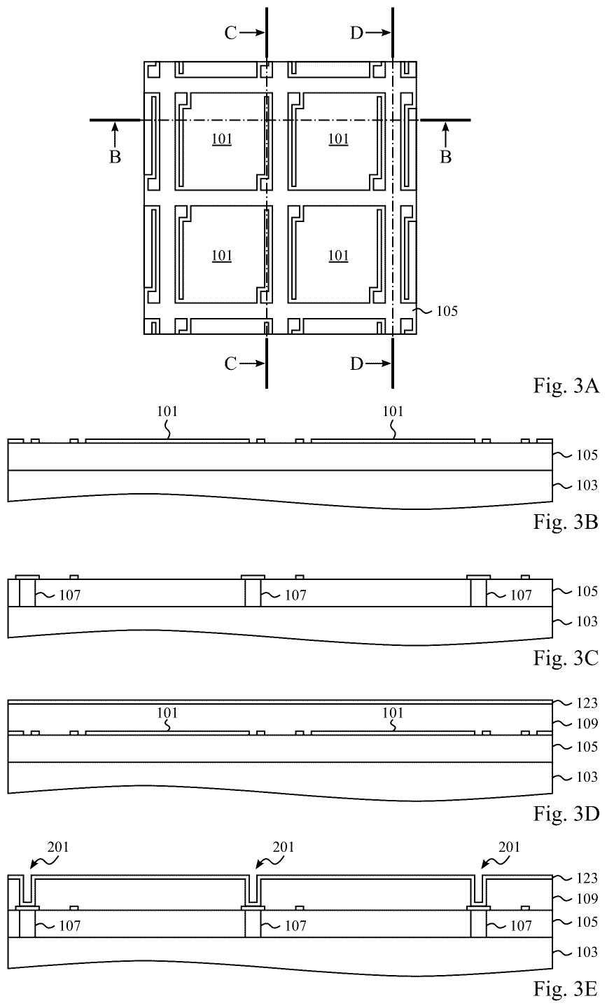

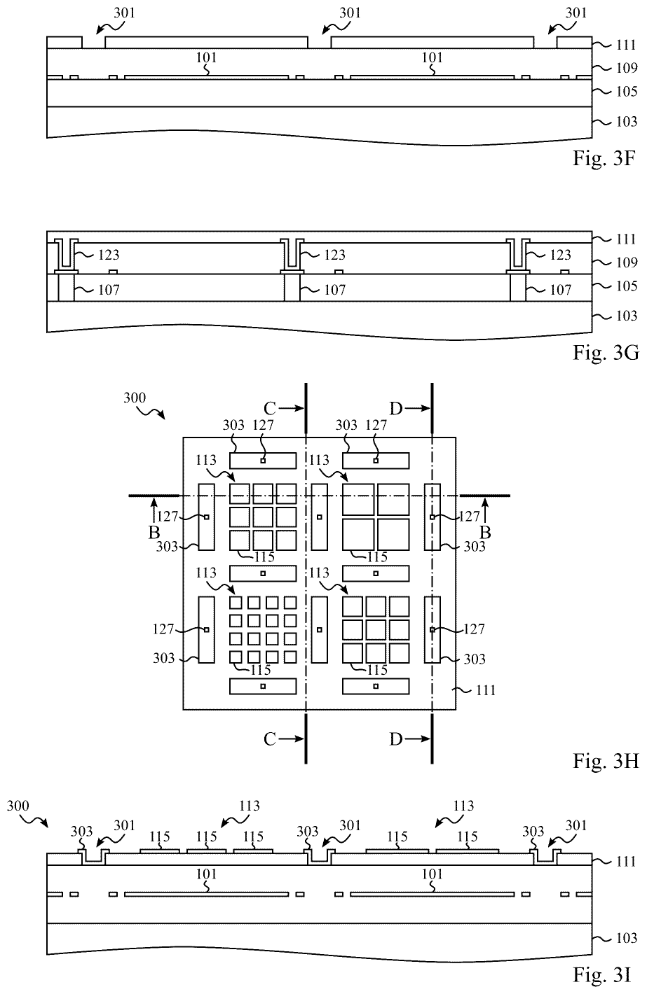

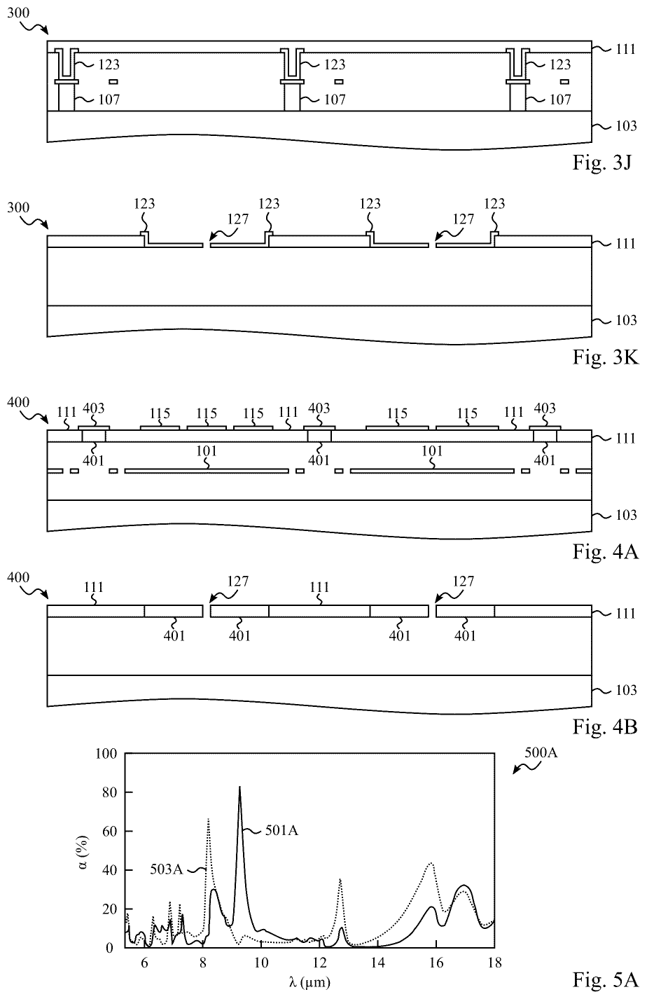

FIG. 3A, FIG. 3B, FIG. 3C, FIG. 3D, FIG. 3E, FIG. 3F, FIG. 3G, FIG. 3H, FIG. 3I, FIG. 3J, and FIG. 3K illustrate, with schematic and partial top, side and cross-sectional views, successive steps of an example method for manufacturing a bolometric sensor 300 according to one embodiment.

The method for manufacturing the bolometric detector 300 has elements in common with the methods for manufacturing the bolometric detectors 100 and 200 described in detail above. These common elements will not be described again in detail hereinafter.

FIG. 3A is a schematic, partial top view of an identical or similar structure to that previously described in relation to FIG. 1A. FIG. 3B and FIG. 3C are side and cross-sectional views, respectively along planes BB and CC shown in FIG. 3A, of the structure.

FIG. 3D and FIG. 3E are schematic, partial side and cross-sectional views, respectively along planes BB and CC shown in FIG. 3A, illustrating a structure obtained at the end of a subsequent step of manufacturing the bolometric sensor 300.

During this step, layer 109 is deposited on the side of the top face of the structure and trenches 201 are formed in line with support pillars 107 as previously explained in relation to FIG. 2A.

Furthermore, during this step, the insulating layer 123 is deposited on the side of the top face of the structure. In the example shown, insulating layer 123 coats the sides and bottom of trenches 201, as well as the upper face of layer 109.

FIG. 3F and FIG. 3G are schematic, partial side and cross-sectional views, respectively along planes BB and CC shown in FIG. 3A, illustrating a structure obtained at the end of a subsequent step of manufacturing the bolometric sensor 300.

During this step, parts of the insulating layer 123 located in line with the bolometer plates 101 are removed. In the example shown in FIG. 3G, portions of insulating layer 123 coating the bottom and sides of trenches 201 are kept.

Furthermore, during this step, the dielectric layer 111 is deposited on the side of the top face of the structure. In the example shown, the layer 111 coats the parts of the insulating layer 123 remaining in the vicinity of the support pillars 107, as well as the parts of the upper face of the layer 109 not coated with the insulating layer 123. In the example shown in FIG. 3G, layer 111 fills the trenches 201. However, this example is not limitative, as layer 111 may alternatively not completely fill the trenches 201.

Furthermore, during this step, trenches 301 are formed in layer 111, for example by photolithography followed by etching. In the example shown, the trenches 301 extend vertically through the entire thickness of the layer 111 from its top surface.

FIG. 3H is a schematic, partial top view illustrating a structure obtained at the end of a subsequent step of manufacturing the bolometric detector 300. FIG. 3I, FIG. 3J, and FIG. 3K are side and cross-sectional views, respectively along planes BB, CC, and DD shown in FIG. 3H, illustrating the same structure.

During this step, an electrically conductive layer is deposited on the side of the top face of the structure previously described in relation to FIGS. 3F and 3G. The diffraction grating 113 is then formed from the electrically conductive layer, for example by photolithography followed by selective etching of the conductive layer with stop on the dielectric layer 111 as previously explained in connection with FIG. 1C. In the example shown, parts 303 of the conductive layer coating the bottom and sides of the trenches 301 remain after etching. Parts 303 of the conductive layer ensure the mechanical strength of the GMR filter and act as optical insulation between the pixels of the detector 300.

Furthermore, during this step, release vents 127 are formed, for example through the thickness of the parts 303 of the conductive layer coating the bottom of the trenches 301.

FIG. 4A and FIG. 4B illustrate, with schematic and partial side and cross-sectional views, respectively along planes BB and DD shown in FIG. 3H, a step in a variant of the method for manufacturing the bolometric detector 300 of FIGS. 3A to 3K.

FIGS. 4A and 4B illustrate more particularly a step of manufacturing a bolometric detector 400 comprising depositing a metal layer 401 on the side of the top face of the structure previously described in relation to FIGS. 3F and 3G. In the example shown, the metal layer 401 fills the trenches 301. The metal layer 401 is then thinned, for example by CMP, with stop on the dielectric layer 111. At the end of this operation, the metal layer 401 is flush with the upper face of the layer 111, for example, and parts of the metal layer 401 located in line with the bolometer plates 101 are removed.

Alternatively, a layer of silicon oxide can be deposited on the upper face of the dielectric layer 111 before the trenches 301 are made. In this case, the trenches 301 extend vertically from the upper face of the silicon oxide layer through the entire thickness of the silicon oxide layer and dielectric layer 111. Thinning the metal layer 401 by CMP then takes place with stop on the silicon oxide layer. The silicon oxide layer is subsequently removed, for example by selective chemical etching with respect to the material of the dielectric layer 111 and the material of the metal layer 401, e.g. by removal in the presence of dilute hydrofluoric acid in the case where the layer 111 is made of amorphous silicon and the layer 401 is made of, for example, tungsten, copper or aluminum.

Furthermore, during this step, an electrically conductive layer is deposited on the side of the top face of the structure. The diffraction grating 113 is then formed from the electrically conductive layer, for example by photolithography and then selective etching with stop on the dielectric layer 111 as previously explained in relation to FIG. 1C. In the example shown, parts 403 of the conductive layer coating parts of the layer 401 are kept at the end of etching.

The material of the conductive layer from which the diffraction grating 113 is formed, and whose parts 403 are kept at the end of the step previously described in relation to FIGS. 4A and 4B, is for example identical to that of the layer 401. Alternatively, the layer from which the diffraction grating 113 is formed and the layer 401 may be made of different materials, such as metals.

Furthermore, during this step, release vents 127 are formed, for example through the thickness of the metal layer 401.

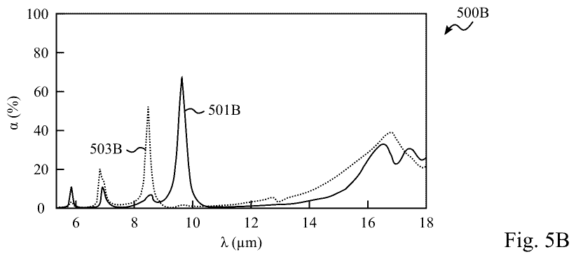

FIG. 5A and FIG. 5B are graphs illustrating absorption spectra of bolometric pixels, translating an evolution of the absorption α (in percent, %) of the bolometric pixel as a function of the wavelength 2 of the incident radiation (in micrometers, μm).

More specifically, FIG. 5A is a graph 500A illustrating absorption spectra 501A and 503A of two pixels of a conventional bolometric detector, the pixels comprising different filters. FIG. 5B is more precisely a graph 500B illustrating absorption spectra 501B and 503B of two pixels of one of the bolometric detectors 100, 200, 300, and 400, the pixels comprising different filters.

As illustrated in FIGS. 5A and 5B, one advantage of the bolometric detectors 100, 200, 300, and 400 described above is that they have reduced rejection losses and less crosstalk phenomena than existing bolometric detectors. In bolometric detectors 100, 200, 300, and 400, the GMR filter rests on the bolometer support pillars 107, which advantageously allows a maximum sensitive surface to be maintained for the bolometer plates 101. Furthermore, the waveguide 111 of the GMR filter of the bolometric detectors 100, 200, 300, and 400 comprises an optical lateral isolation between the different pixels, thus allowing crosstalk to be limited and rejection performance to be improved.

In bolometric detectors 300 and 400, the support elements of the GMR filter resting on the support pillars 107 each comprise a region of the dielectric layer 111, whose sides and bottom are coated with part of the insulating layer 123. In this case, the support elements of the GMR filter are made entirely of one or more dielectric materials. In the bolometric detector 200, the support elements of the GMR filter comprise a single dielectric material.

Various embodiments and variants have been described. Those skilled in the art will understand that certain features of these embodiments can be combined and other variants will readily occur to those skilled in the art. In particular, although examples of bolometer detectors 100, 200, 300, and 400 using silicon oxide sacrificial layers have been described in detail above, the embodiments described are not limited to this case but apply more generally to any type of bolometer technology. Furthermore, although the description takes as an example bolometric detectors suitable for capturing LWIR infrared radiation, this example is not a limitation, as the embodiments of the present description apply to bolometric detectors capable of capturing infrared radiation in any range.

Furthermore, although examples of bolometric detectors 100, 200, 300, and 400 comprising a filter for each pixel have been described, the embodiments are not limited to these examples. In particular, some pixels of the detector may be filter-free, for example in the case of white pixels or broadband pixels. At least one of the pixels of the detector thus comprises a guided-mode filter comprising a planar waveguide resting on support pillars of a bolometric plate and a diffraction grating located on and in contact with the waveguide. Those skilled in the art is able to manufacture such a device from the indications of the above description.

Finally, the practical implementation of the embodiments and variants described herein is within the capabilities of those skilled in the art based on the functional description provided hereinabove. In particular, the embodiments described are not limited to the particular examples of materials and dimensions mentioned in the present description.

1. A bolometric detector comprising a plurality of pixels each including a bolometric plate suspended above a substrate by support pillars, the detector further comprising, for at least one of said pixels, a guided-mode filter comprising a planar waveguide resting on the support pillars, and a diffraction grating located on and in contact with the waveguide.

2. The detector according to claim 1, wherein the guided-mode filter comprises support elements resting on the support pillars.

3. The detector according to claim 2, wherein each support element comprises an electrically conductive region whose sides and bottom are coated with an electrically insulating layer.

4. The detector according to claim 2, wherein each support element is made of a single dielectric region.

5. The detector according to claim 4, wherein at least two adjacent pixels of the detector comprise the guided-mode filter, the planar waveguides of said pixels being optically isolated by an electrically conductive region whose flanks and bottom are coated with an electrically insulating layer.

6. The detector according to claim 2, wherein each support element comprises a dielectric region made of a first material, the sides and bottom of said region being coated with an insulating layer made of a second material, different from the first material.

7. The detector according to claim 6, wherein the first material is amorphous silicon.

8. The detector according to claim 6, wherein the second material is alumina.

9. The detector according to claim 6, wherein at least two adjacent pixels comprise the guided-mode filter, the planar waveguides of said pixels being optically isolated by an electrically conductive region.

10. The detector according to claim 9, wherein the electrically conductive region and the diffraction grating are made of a same material, preferably a metal.

11. The detector according to claim 9, wherein the electrically conductive region and the diffraction grating are made of different materials, preferably metals.

12. The detector according to claim 1, wherein the diffraction grating comprises a plurality of pads located on and in contact with the top face of the planar waveguide.

13. A method for manufacturing a bolometric detector according to claim 1, comprising the following steps:
a) forming the support pillars and bolometric plates above the substrate;
b) depositing a first sacrificial layer on the side of the top face of the structure;
c) forming, for said at least one of said pixels, the planar waveguide and diffraction grating;
d) forming vias through the entire thickness of the first dielectric layer in line with each support pillar;
e) depositing a second insulating layer on the side of the top face of the structure; and
f) depositing an electrically conductive layer on the side of the top face of the structure.

14. The method according to claim 13, wherein step f) is implemented after step e).

15. The method according to claim 13, wherein step f) is implemented before step c).
